(19) United States
(12) Patent Application Publication
(10) Pub. No.: US 2022/0270866 A1
(43) Pub. Date: Aug. 25, 2022

(54) APPARATUS FOR PERFORMING SPUTTERING PROCESS AND METHOD THEREOF

(71) Applicant: Tokyo Electron Limited, Tokyo (JP)

(72) Inventors: Tetsuya MIYASHITA, Nirasaki City (JP); Naoki WATANABE, Nirasaki City (JP)

(21) Appl. No.: 17/676,411

(22) Filed: Feb. 21, 2022

(30) Foreign Application Priority Data
Feb. 24, 2021 (JP) 2021-027688

(51) Int. Cl. H01J 37/34; H01J 37/32; C23C 14/35

(52) U.S. Cl. CPC H01J 37/3455; H01J 37/32733; C23C 14/35

(57) ABSTRACT

An apparatus for performing a sputtering process on a substrate includes: a processing container configured to accommodate a plurality of substrates; a plurality of stages provided inside the processing container to respectively place the plurality of substrates thereon and disposed to be arranged along a circle surrounding a preset center position; and a target disposed at a position above the stages to cause target particles to be emitted by plasma formed inside the processing container such that the target particles adhere to the substrates respectively placed on the stages, wherein the stages are arranged such that an emission region in which the target particles are emitted from the target and overlapping regions in which the substrates respectively placed on the stages overlap are arranged at positions that are rotationally symmetrical around the preset center position when viewed in a plan view from above the target.

### CROSS-REFERENCE TO RELATED APPLICATION

This application is based upon and claims the benefit of priority from Japanese Patent Application No. 2021-027688 filed on Feb. 24, 2021, the entire contents of which are incorporated herein by reference.

### TECHNICAL FIELD

The present disclosure relates to an apparatus for performing a sputtering process and a method thereof.

### BACKGROUND

In a semiconductor device manufacturing process, a magnetron sputtering apparatus is used for forming a metal film or the like. This apparatus is configured such that a target made of a material to be deposited is disposed inside a vacuum processing container and a magnetic field and an electric field are generated inside the processing container to generate plasma so as to sputter the target with plasma ions.

For example, Patent Document 1 discloses a low-pressure remote sputtering apparatus in which a plurality of sets of holder bases that rotate via an auxiliary drive shaft are provided around a main drive shaft that rotates a base support stage, and a plurality of substrates are arranged around the auxiliary drive shaft. In this apparatus, when processing the plurality substrates held on the holder bases, film formation is performed by causing sputtered particles to be emitted from the target while combining rotation around the auxiliary drive shaft with rotation around the main drive shaft.

### PRIOR ART DOCUMENT

### Patent Document

Patent Document 1: Japanese Laid-Open Patent Publication No. H10-298752

### SUMMARY

According to one embodiment of the present disclosure, there is provided an apparatus for performing a sputtering process on a substrate, including: a processing container configured to accommodate a plurality of substrates; a plurality of stages provided inside the processing container to respectively place the plurality of substrates thereon and disposed to be arranged along a circle surrounding a preset center position; and a target disposed at a position above the plurality of stages to cause target particles to be emitted by plasma formed inside the processing container such that the target particles adhere to the plurality of substrates respectively placed on the plurality of stages, wherein the plurality of stages are arranged such that an emission region in which the target particles are emitted from the target and overlapping regions in which the plurality of substrates respectively placed on the plurality of stages overlap are arranged at positions that are rotationally symmetrical around the preset center position when viewed in a plan view from above the target.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a plan view of a substrate processing system according to an embodiment.

FIG. 2 is a vertical cross-sectional side view of a sputtering apparatus provided in the substrate processing system.

FIG. 3 is a schematic view illustrating a movement range of a magnet for plasma adjustment with respect to a target.

FIG. 4 is a plan view illustrating an arrangement of a target and stages of the sputtering apparatus.

FIG. 5 is a plan view illustrating an arrangement of a target and stages according to a comparative example.

FIG. 6 is a schematic view illustrating a second configuration example of a target and stages.

FIG. 7 is a schematic view illustrating a third configuration example of a target and stages.

FIG. 8 is a schematic view illustrating a fourth configuration example of a target and stages.

FIG. 9 is a schematic view illustrating a fifth configuration example of a target and stages.

FIG. 10 is a plan view illustrating another configuration example of a magnet.

FIG. 11 is a schematic view illustrating a sixth configuration example of a target and stages.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

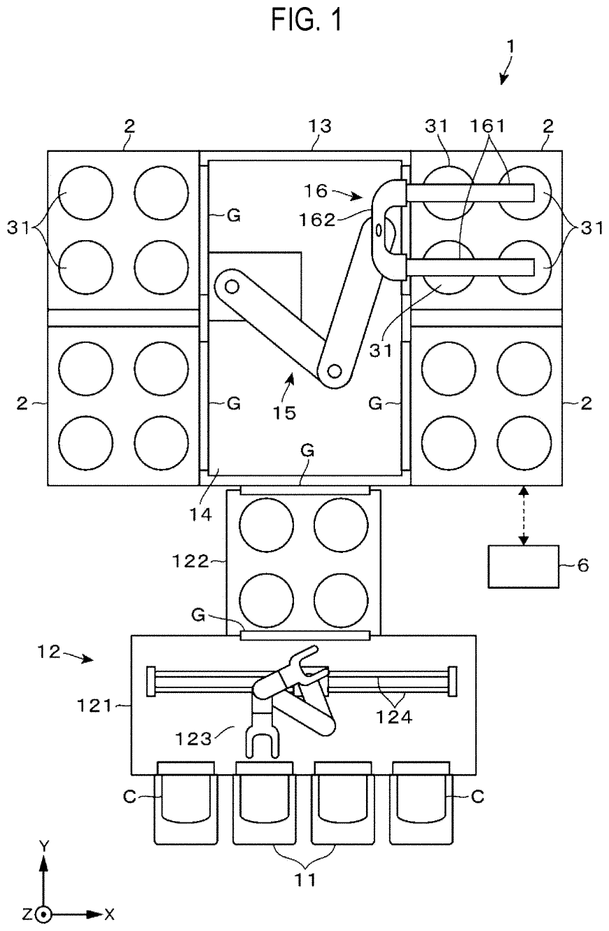

FIG. 1 illustrates a configuration example of a substrate processing system 1 provided with a sputtering apparatus 2 according to the present disclosure. The substrate processing system 1 includes a carry-in/out port 11, a carry-in/out module 12, a vacuum transfer module 13, and a plurality of sputtering apparatuses 2. In FIG. 1, the left-right direction is referred to as the X direction and the front-back direction is referred to as the Y direction from the carry-in/out port 11 toward the substrate processing system 1. The carry-in/out port 11 is connected to the front side of the carry-in/out module 12, and the vacuum transfer module 13 is connected to the rear side of the carry-in/out module 12.

A carrier C, which is a transfer container accommodating a substrate to be processed, is placed in the carry-in/out port 11. The carrier C accommodates a plurality of wafers W, which are circular substrates having a diameter of, for example, 300 mm. The carry-in/out module 12 is a facility for performing carry-in/out of the wafer W between the carrier C and the vacuum transfer module 13. The carry-in/out module 12 includes an atmospheric transfer chamber 121 provided with a transfer mechanism 123 for performing delivery and transfer of the wafer W in a normal pressure atmosphere, and a load-lock chamber 122 configured to switch the atmosphere in which the wafer W is placed between a normal pressure atmosphere and a vacuum atmosphere. The transfer mechanism 123 is configured to be movable in the left-right direction along a rail 124, and to be capable of being raised/lowered/rotated/expanded/contracted.

The vacuum transfer module 13 includes a vacuum transfer chamber 14 in which a vacuum atmosphere is formed, and a substrate transfer mechanism 15 is arranged inside the vacuum transfer chamber 14. The vacuum transfer chamber 14 of this example is configured to have a rectangular shape having long sides extending in the front-rear direction when viewed in a plan view. Among the four sidewalls of the vacuum transfer chamber 14, a plurality of (e.g., two) sputtering apparatuses 2 are connected to each of the long sides facing each other. The load-lock chamber 122 is connected to the short side on the front side. Reference numeral G in the figure indicates gate valves interposed between the carry-in/out module 12 and the vacuum transfer module 13 and between the vacuum transfer module 13 and the sputtering apparatuses 2, respectively. The gate valves G open and close the carry-in/out ports for the wafer W provided in respective modules connected to each other.

The substrate transfer mechanism 15 of this example is configured as an articulated arm for transferring the wafer W between the carry-in/out module 12 and each sputtering apparatus 2, and includes an end effector 16 configured to hold the wafer W. As will be described later, the sputtering apparatus 2 in this example collectively performs a sputtering process on the plurality of (e.g., four) wafers W in a vacuum atmosphere. Therefore, in order to collectively deliver the wafers W to the sputtering apparatus 2, the end effector 16 of the substrate transfer mechanism 15 is configured to be capable of holding, for example, four wafers W at the same time.

The end effector 16 includes a substrate holder 161 and a connecting portion 162. The substrate holder 161 includes two elongated spatula-shaped members extending horizontally in parallel with each other. The connecting portion 162 extends in the horizontal direction to be orthogonal to the extending direction of the substrate holder 161 and connects two base ends of the substrate holder 161 to each other. The central portion of the connecting portion 162 in the length direction is connected to the tip end of the articulated arm constituting the substrate transfer mechanism 15. The substrate transfer mechanism 15 is configured to be capable of swiveling and expanding/contracting.

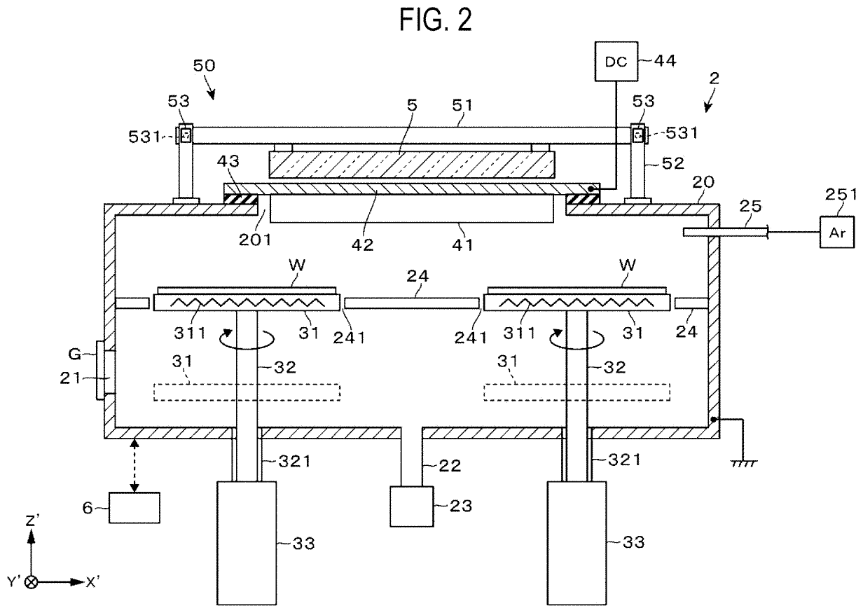

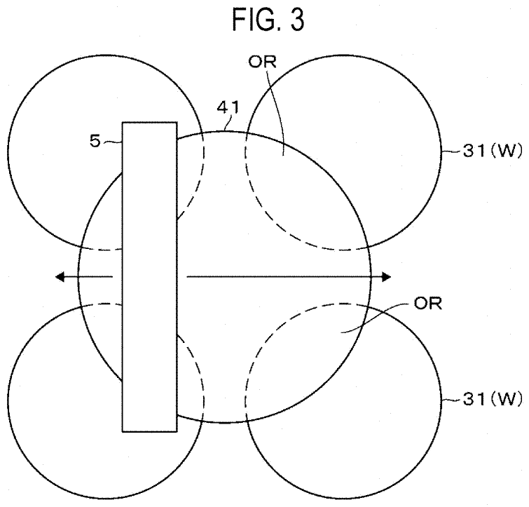

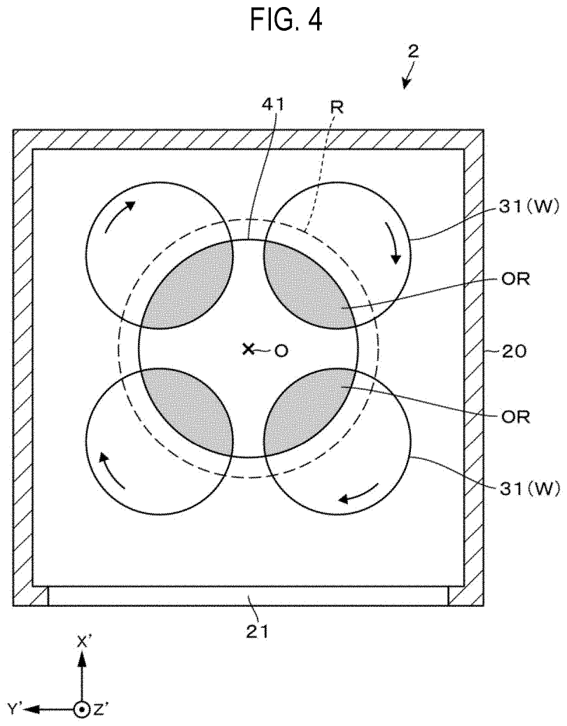

Next, a configuration of the sputtering apparatus 2 for forming a film on the wafer W through a sputtering process will be described with reference to FIGS. 2 to 4. FIG. 2 is a vertical cross-sectional side view illustrating the configuration of the sputtering apparatus 2, and FIGS. 3 and 4 are plan views illustrating an arrangement of a target 41 and stages 31, and the like. In addition, in FIGS. 2 and 4, sub-coordinates (X′-Y′-Z′ coordinates) for explaining an arrangement relationship between devices in the sputtering apparatus 2 are also indicated. In the sub-coordinates, a position at which the sputtering apparatus is connected to the vacuum transfer module 13 is set as a front side, the X′ direction is set as the front-rear direction, and the Y′ direction is set as the left-right direction.

The four sputtering apparatuses 2 connected to the vacuum transfer module 13 are configured in the same manner as each other, and the plurality of sputtering apparatuses 2 are capable of processing the wafers W in parallel with each other.

The sputtering apparatus 2 includes a processing container 20 having a rectangular shape in a plan view. The processing container 20 is configured as a vacuum container capable of evacuating an internal atmosphere. A carry-in/out port 21 connected to the vacuum transfer chamber 14 via a gate valve G is formed on the sidewall on the front side of the processing container 20. The carry-in/out port 21 is opened/closed by the gate valve G.

Inside the processing container 20, four stages 31 are arranged to correspond to the positions at which transfer of the wafers W is performed by the end effector 16. Each stage 31 is formed of a disk-shaped member. In this example, the wafer W is placed on each stage 31 such that the center of the disk-shaped stage 31 and the center of the wafer W are aligned with each other.

In addition, these plurality of stages 31 are in a state of being arranged at specific positions in relation to the planar shape and arrangement of the target 41 to be described later, but a specific setting example of the arrangement will be described later.

Each stage 31 is supported by a support column 32 at the center position of the disk from the bottom side. The lower side of the support column 32 penetrates the bottom surface of the processing container 20 and protrudes downward. A lower end portion of the support column 32 is provided with a drive mechanism 33 configured to rotate the stage 31 around a vertical axis passing through the center of the wafer W placed on the stage 31. From this point of view, the drive mechanism 33 corresponds to a rotation mechanism of this example. In a case in which a film having a desired film thickness distribution can be formed without rotating the wafer W, it is not an essential requirement to rotate the stage 31 using the drive mechanism 33.

Reference numeral 321 indicated in FIG. 2 indicates cover members, each of which is provided between the periphery of an opening through which the support column 32 penetrates the bottom surface of the processing container 20 and the top surface of the corresponding drive mechanism 33 to surround the periphery of the support column 32 in order to maintain the interior of the processing container 20 in a vacuum atmosphere.

The drive mechanism 33 also has a function of raising and lowering the stage 31 between a processing position at which the sputtering process for the wafer W is performed and a delivery position at which the wafer W is delivered to/from the end effector 16. A height position at which the stages 31 are arranged in FIG. 2 corresponds to the processing position, and a height position indicated by the broken lines in FIG. 2 corresponds to the delivery position.

In the processing container 20, a shield plate 24 that divides the internal space of the processing container into upper and lower portions is disposed. Circular openings 241 are formed in the shield plate 24, and the stages 31 raised to the processing position are in the state of being arranged inside the openings 241, respectively.

Delivery pins (not illustrated) are provided on the bottom surface of the processing container 20. When the stages 31 are lowered to the delivery position, the delivery pins protrude from the top surfaces of the stages 31 through through-holes (not illustrated) provided in the stages 31. As a result, the delivery of the wafers W can be performed between the delivery pins and the end effector 16.

A heater 311 is embedded in each stage 31, and generates heat by electric power supplied from a power feeder (not illustrated) to heat the wafer W placed on the stage 31. As a temperature of heating the wafer W by the stage 31, a temperature in the range of 50 to 450 degrees C. may be exemplified.

A circular opening 201 is formed in the center of the top surface of the processing container 20. The target 41 is provided inside the opening 201. A conductive target electrode 42 made of, for example, copper (Cu) or aluminum (Al) is bonded to the top surface of the target 41. For example, the target electrode 42 is arranged on the top surface of the processing container 20 via an annular insulating member 43. As a result, the above-mentioned opening 201 provided in the top surface of the processing container 20 is closed by the target electrode 42.

A DC power supply 44 is connected to the target 41. Plasma can be formed in the processing container 20 by DC power supplied from the DC power supply 44. Instead of the DC power, AC power may be applied to generate plasma.

The target 41 emits target particles, which adhere to the wafers W, by the plasma formed inside the processing container 20, thereby performing film formation. For example, the target 41 is composed of titanium (Ti), silicon (Si), zirconium (Zr), hafnium (HD, tungsten (W), a cobalt-iron-boron alloy, a cobalt-iron alloy, iron (Fe), tantalum (Ta), ruthenium (Ru), magnesium (Mg), iridium manganese (IrMn), platinum manganese (PtMn), or the like. In addition, as the target 41, an insulator such as SiO₂ may be used in addition to the metal.

A magnet 5 made of a permanent magnet for adjusting the state of plasma formed inside the processing container 20 is arranged on the rear side of the target 41 when viewed from the side of the stages 31. Specifically, the magnet 5 is held by a magnet moving mechanism 50 and is arranged at a height position spaced apart from the top surface of the target electrode 42 bonded to the target 41 by about several millimeters.

As schematically illustrated in FIG. 3, the magnet 5 of this example is formed in an elongated rectangular shape when viewed in a plan view. The long sides of the magnet 5 are longer than the diameter of the target 41 formed in a circular shape. The magnet 5 may be formed by an electromagnet that generates a magnetic field when electric power is supplied to an electromagnetic coil thereof.

For example, the magnet moving mechanism 50 includes an elongated rod-shaped magnet holder 51. The magnet 5 is held on the bottom side of the magnet holder 51. Ball screws 531, each of which penetrates the magnet holder 51, are provided at opposite ends of the magnet holder 51. Opposite ends of each ball screw 531 are supported by support columns 52 arranged on the top surface of the processing container 20. Each ball screw 531 can be rotationally driven by a drive motor 53 provided at the end portion thereof. The magnet 5 can be horizontally moved by rotating both ball screws 531 in a state in which rotation direction and rotation speed are in synchronization with each other.

With the above-described configuration, as indicated by the arrows in FIG. 3, the magnet 5 of this example reciprocates on the top side of the target 41 to scan the entire surface of the target 41. As a result, when viewed in a plan view from above the target 41, the entire surface of the target 41 is enclosed in the region in which the magnet 5 moves. In addition, since the plasma generation region moves in accordance with the reciprocating movement of the magnet 5, the entire surface of the target 41 becomes an emission region in which the target particles are emitted.

For the sake of convenience in illustration, the illustration of the magnet moving mechanism 50, the target electrode 42, the processing container 20, and the like is omitted in FIG. 3.

Returning to the description of FIG. 2, the sidewall of the processing container 20 is provided with a supply port 25 for supplying a plasma-generating gas toward a space (a processing space) above the shield plate 24. A plasma gas source 251 is connected to the supply port 25. For example, an argon (Ar) gas is supplied from the plasma gas source 251 as the plasma-generating gas.

In the sputtering apparatus 2 having the configuration described above, the target 41 and the stages 31 have a special arrangement relationship in which a film having a uniform film thickness is formed in the plane of each wafer W. In addition, according to this arrangement relationship, it is possible to perform film formation with a uniform film thickness distribution even in inter-planes of the plurality of wafers W to be sputtered in the processing container 20.

Hereinafter, the arrangement relationship between the target 41 and the stages 31 in the sputtering apparatus 2 of this example will be described with reference to FIG. 4. FIG. 4 is a perspective view of the sputtering apparatus 2 when viewed from above the target 41 in a plan view. In the figure, the illustration of the magnet moving mechanism 50, the magnet 5, the target electrode 42, and the like is omitted, and the illustration is focused on the arrangement relationship between the target 41 and the stages 31.

Furthermore, as described above, the wafer W is placed on each stage 31 such that the center of the disk-shaped stage 31 and the center of the wafer W are aligned with each other. Therefore, ignoring a difference in diameter between each stage 31 and the wafer W, it can be said that FIG. 4 illustrates the arrangement position of the wafer W placed on each stage 31 (the same applies to FIGS. 3 to 11).

At this time, in the sputtering apparatus 2 of this example illustrated in FIG. 4, the plurality of stages 31 are arranged such that the center positions of respective stages 31 are arranged along a circle R surrounding a preset center position O. In the example illustrated in FIG. 4, the diameter of the circle R is set to a dimension in which the circle R encloses the entire surface of the target 41 when viewed in a plan view from above the target 41. It is necessary to provide the target 41 having such a size that the target particles reach the entire surface of the rotating wafers W. However, by adopting the above-described configuration, it is possible to efficiently perform the sputtering process while suppressing an increase in the size of the target 41.

In the following description, regions in which an emission region, which is a region in which the target particles are emitted, and wafers W respectively placed on the plurality of stages 31 overlap when viewed from above the target 41 in a plan view will be referred to as “overlapping regions OR.” In this example, the entire surface of the target 41 corresponds to the emission region. In FIG. 4 and FIGS. 6 to 9 and 11 to be described later, the overlapping regions OR are indicated in a gray color.

In the sputtering apparatus 2 of this example, the overlapping regions OR are arranged at positions that are rotationally symmetrical around the above-mentioned center position O. In the example illustrated in FIG. 4, four overlapping regions OR are formed between four stages 31 and one target 41. In addition, these overlapping regions OR are formed around the above-mentioned center position O at positions that are symmetrical four times so as to overlap when rotated by 90 degrees.

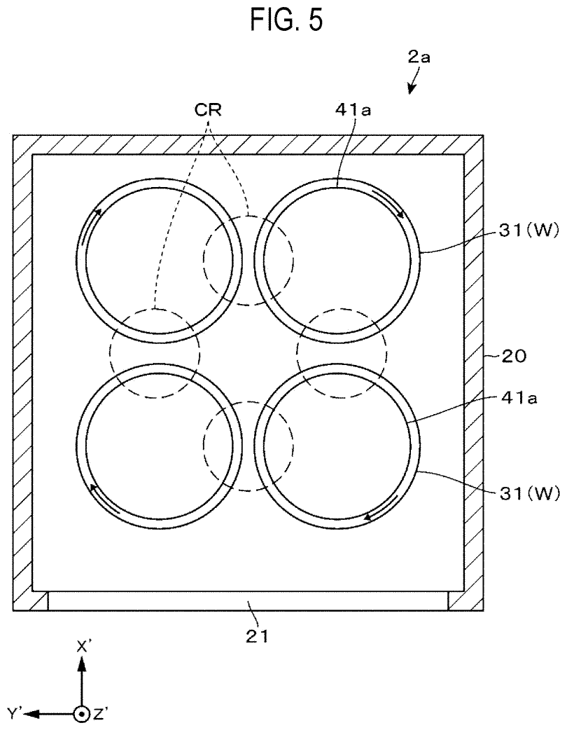

Here, for ease of understanding the characteristics of the arrangement of the target 41 and the stages 31 in FIG. 4, a description will be made while comparing with a sputtering apparatus 2a according to a comparative embodiment illustrated in FIG. 5.

As described above, there is a problem of providing a plurality of stages 31 in a common processing container 20 and forming a film having a uniform thickness in the plane of the wafer W placed on each stage 31. In this case, as illustrated in FIG. 5, it may be considered that it is possible to perform uniform film formation by providing a plurality of targets 41a to face the plurality of stages 31 (wafers W), respectively, and supplying target particles from each target 41a to the entire surface of individual wafer W.

However, under a condition that the footprint of the apparatus is limited, the plurality of stages 31 are required to be arranged at positions close to each other as illustrated in FIG. 5. In this case, when the targets 41a are arranged above the stages 31, respectively, the targets 41a are also required to be arranged at close positions. As a result, the target particles emitted from one target 41a may also reach wafers W arranged below the other adjacent targets 41a.

For example, in the example of the arrangement illustrated in FIG. 5, two targets 41a are arranged at positions close to each other in a proximity region CR surrounded by a broken line. At this time, the target particles emitted from these targets 41a may also reach wafers W arranged under the other targets 41a adjacent to each other. In this case, even when the wafers W (the stages 31) are rotated using the drive mechanisms 33, respectively, a concave film thickness distribution in which the film is thick at the peripheral portion of each wafer W and thin at the central portion thereof may be formed.

In order to avoid the formation of such a film thickness distribution, it is necessary to arrange the stages 31 sufficiently apart from each other, which may lead to an increase in the footprint of the sputtering apparatus 2 or the substrate processing system 1.

Therefore, as described above, in the sputtering apparatus 2 of this example, an arrangement, in which the plurality of overlapping regions OR in which the stages 31 and the target 41 appear to overlap each other are rotationally symmetrical around the center position O (in this example, symmetrical 4 times) when viewed in a plan view, is adopted. Unlike the comparative embodiment described with reference to FIG. 5, in this configuration, target particles are supplied from one target 41 to the wafers W placed on the stages 31.

As described above, the substrate processing system 1 and the sputtering apparatus 2 having the configurations described above with reference to FIGS. 1 to 4 include a controller 6. The controller 6 is configured with, for example, a computer including a CPU and a storage part (not illustrated). The storage part of the controller 6 stores a program that incorporates a group of steps (instructions) relating to the control required to execute an operation of performing the transfer of the wafers W between the carrier C loaded in the carry-in/out port 11 and each sputtering apparatus 2 or an operation of performing the film formation on the wafers W in each sputtering apparatus 2. The program may be stored in a storage medium such as a hard disk, a compact disk, a magnetic-optical disk, a memory card, or the like, or may be installed from the storage medium on the computer.

Next, the operations of the above-described substrate processing system 1 and sputtering apparatus 2 will be described.

When the carrier C accommodating the wafers W to be processed is placed on the carry-in/out port 11, the transfer mechanism 123 receives the wafers W and transfers the same into the load-lock chamber 122 via the atmospheric transfer chamber 121. Subsequently, after switching the interior of the load lock chamber 122 from a normal pressure atmosphere to a vacuum atmosphere, the substrate transfer mechanism 15 of the vacuum transfer module 13 receives the wafers W and transfers the same to a predetermined sputtering apparatus 2 via the vacuum transfer chamber 14. As described above, the substrate transfer mechanism 15 enters the processing container 20 in the state of holding a total of four wafers W on the end effector 16. Then, after these wafers W are delivered from the end effector 16 to delivery pins (not illustrated), the end effector 16 is retracted from the processing container 20 and the gate valve G closes the carry-in/out port 21. Thereafter, each stage 31 that has been retracted to the delivery position is raised, and the wafers W are delivered from the delivery pins to these four stages 31 at the same time.

Subsequently, while raising each stage 31 to the processing position, the supply of the plasma-generating gas from the supply port 25, the adjustment of the internal pressure of the processing container 20, and the heating of the wafers W by the heaters 311 are performed. In addition, the rotation of the stages 31 by the drive mechanisms 33 is initiated.

Thereafter, the DC power is applied from the DC power supply 44 to the target electrode 42. As a result, an electric field is generated around the target electrode 42, and electrons accelerated by this electric field collide with the Ar gas to ionize the Ar gas, whereby new electrons are generated.

Meanwhile, when the movement of the magnet 5 by the magnet moving mechanism 50 is initiated, a magnetic field is formed on the surface of the target 41 according to the arrangement position of the magnet 5, and electrons ionized from the Ar gas are accelerated by the electric field and the magnetic field near the target 41. Due to this acceleration, a phenomenon in which electrons with energy further collide with the Ar gas to cause ionization successively occurs to form plasma. The Ar ions in the plasma sputter the target 41, whereby target particles are emitted.

In this way, the target particles are radially emitted from the surface of the target 41 located under the magnet 5 toward the wafers W on the stages 31. As a result, the target particles reach and adhere to the wafers W. Then, by reciprocating the magnet 5 as described with reference to FIG. 3, the target particles can be emitted using the entire surface of the target 41 as the emission region.

As described above, in the sputtering apparatus 2 of this example, the overlapping regions OR between the stages 31 and the target 41 are arranged to be rotationally symmetrical around the center position O of the circle R formed by arranging the center positions of the plurality of stages 31. According to this configuration, even when the plurality of stages 31 are arranged in a compact region, target particles are supplied from one target 41 to the wafer W placed on each stage 31. As a result, unlike the sputtering apparatus 2a according to the comparative embodiment described with reference to FIG. 5, a uniform film can be formed without being affected by the target particles from other targets 41a arranged at close positions.

Since respective stages 31 are arranged to be rotationally symmetrical with respect to the disk-shaped target 41, a difference in film thickness distribution due to a difference in the arrangement positions of the stages 31 may be less likely to occur. This makes it possible to perform film formation in which the film thickness distribution is uniform even in the inter-planes of the wafers W.

When a predetermined period of time elapses and the film formation by the sputtering process is completed, the supply of the Ar gas and the DC power, the heating of the wafers W, and the rotation of the stages 31 are stopped, and the internal pressure of the processing container 20 is adjusted. Then, the four wafers W after the film formation are simultaneously carried out from the processing container 20 via a procedure opposite to that at the time of carry-in.

In addition, the wafers W taken out from the processing container 20 are returned to the carrier C on the carry-in/out port 11 in the order of the vacuum transfer module 13, the load-lock chamber 122, and the atmospheric transfer chamber 121 via the route opposite to that at the time of carry-in.

According to the sputtering apparatus 2 according to the present embodiment, it is possible to perform an in-plane and inter-plane uniform sputtering process on the plurality of wafers W arranged in the common processing container 20.

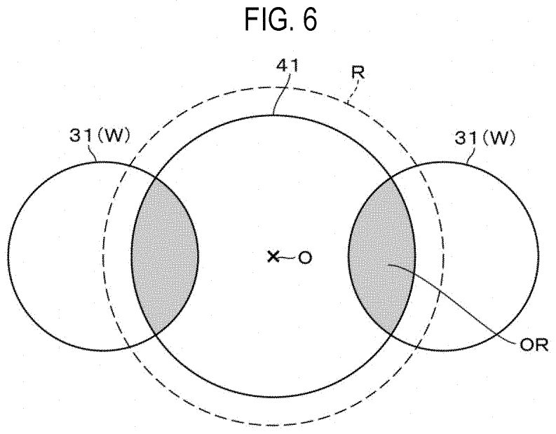

Next, with reference to FIGS. 6 to 11, variations in the arrangement of the stages 31, the planar shape of the target 41, and the like will be described. In these figures, the relationship between the arrangement position of the target 41 and the stages 31 will be mainly described, and the description of the processing container 20 and the like will be omitted as appropriate.

The number of stages 31 provided inside the processing container 20 is not limited to the example described with reference to FIG. 4, and three or less stages 31 may be provided, or five or more stages 31 may be provided. For example, FIG. 6 illustrates an example in which two stages 31 are provided along a circle R and the arrangement positions of these stages 31 are set such that overlapping regions OR are formed at positions that are symmetrical twice.

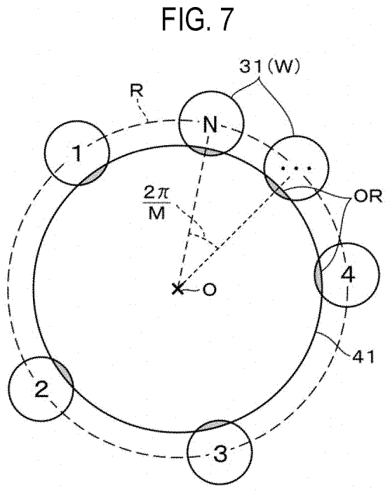

In general, when the stages 31 are arranged such that the overlapping regions OR are symmetrical M times, it is not an essential requirement to arrange a total of M stages 31 at all positions satisfying this condition. FIG. 7 illustrates an example in which the circle R is divided into M in the circumferential direction, and N stages 31 which are smaller than the number of divisions M are used to form overlapping regions OR at positions that are symmetrical around the center position O about M times.

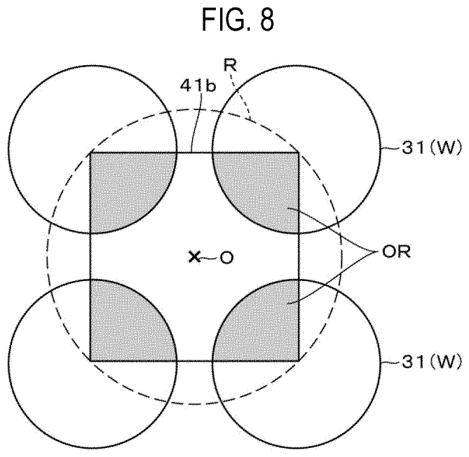

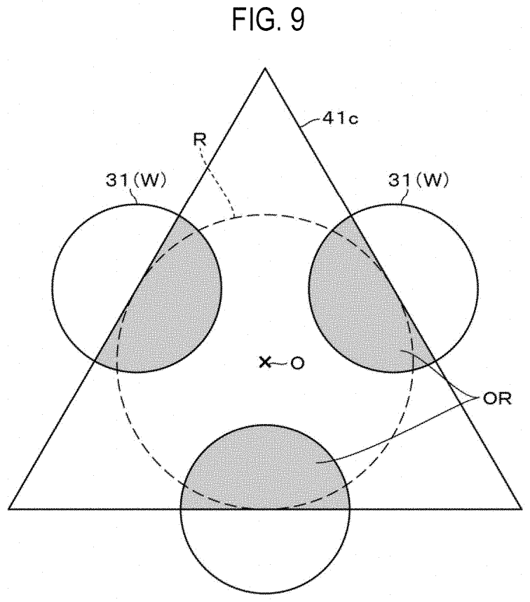

In addition, the shapes of targets 41b and 41c are not limited to a circle. For example, FIG. 8 illustrates an example in which the apexes of the target 41b having a square planar shape and the centers of the stages 31 are aligned and arranged. In this case, overlapping regions OR are formed to be symmetrical four times. In addition, FIG. 9 illustrates an example in which the midpoints of respective sides of the target 41c having an equilateral triangle shape and the center of the stages 31 are aligned and arranged. In this case, the overlapping regions OR are formed to be symmetrical three times.

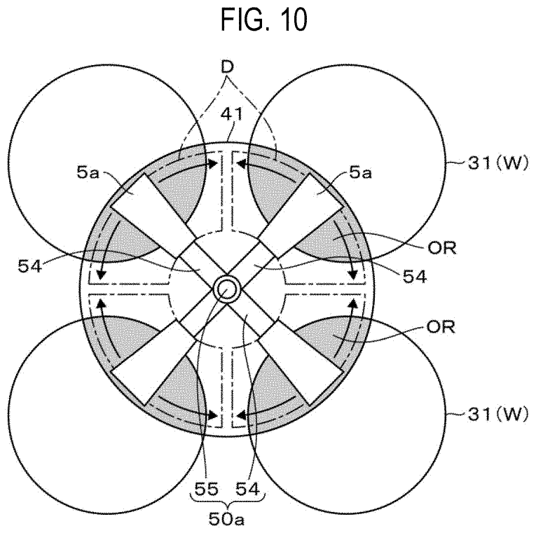

Next, FIG. 10 illustrates an example in which a magnet 5a and a magnet moving mechanism 50a having configurations different from those described with reference to FIGS. 2 and 3 are provided. In this example, four elongated magnets 5a configured to extend along the radial direction of the circular target 41 are provided to correspond to four stages 31. Each magnet 5a is connected to a rotation shaft 55 provided in the center of the target 41 via an arm portion 54. The rotation shaft 55 is configured to be rotatable in both a clockwise forward rotation direction and a counterclockwise reverse rotation direction by a rotary drive part (not illustrated). The arm portion 54, the rotation shaft 55, and the rotation drive part (not illustrated) constitute the magnet moving mechanism 50a of this example.

Using the magnet moving mechanism 50a illustrated in FIG. 10, the magnets 5a are reciprocated in the forward rotation direction and the reverse rotation direction so as to scan the overlapping regions OR. By this operation, fan-shaped emission regions D illustrated by the alternate long and short dash lines in FIG. 10 are formed on the target 41 to correspond to the ranges in which the magnets 5a move. In this example, since four magnets 5a are provided to correspond to the arrangement positions of the four stages 31, by reciprocating these magnets 5a, a substantially annular emission region D (an emission region D having a circular outer edge) when viewed in a plan view from above is formed in the target 41.

In the example illustrated in FIG. 10, it is illustrated that the end portions of the fan-shaped emission regions D do not overlap each other for the purpose of clarifying the shape of the emission regions D formed by the respective magnets 5a. Meanwhile, the reciprocating ranges of the magnets 5a may be set such that these emission regions D overlap each other. In addition, in the configuration illustrated in FIG. 10, it is not an essential requirement to reciprocate the magnets 5a only in the range in which the overlapping regions OR are scanned. For example, the magnets 5a may be rotationally moved in the forward rotation direction or the reverse rotation direction. In this case, the sputtering process may be performed using magnets 5a the number of which is larger or smaller than the number of overlapping regions OR.

Here, in the example described with reference to FIGS. 3 and 4, the movement ranges of the magnets 5 are set such that the entire surface of the target 41 is enclosed in the area in which the magnets 5 move when viewed in a plan view from above the target 41. With this setting, the emission region in which target particles are emitted becomes the entire surface of the target 41.

By contrast, in the example described with reference to FIG. 10, the emission regions D are partial regions of the target 41 exposed in the processing container 20. When the partial regions of the target 41 are set as emission regions D in this way, the magnets 5a may be moved to correspond to the shape of the emission regions D, respectively.

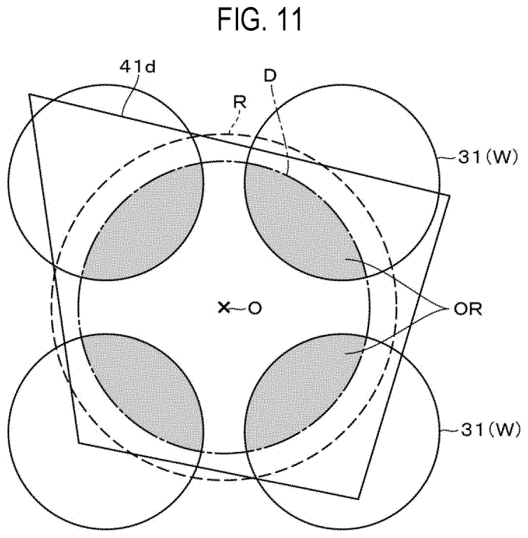

FIG. 11 illustrates an example in which a circular emission region D is formed in a target 41d having an arbitrary planar shape when viewed in a plan view. Even when the contour of the target 41d is not rotationally symmetrical around the center position O as in this example, overlapping regions OR arranged to be rotationally symmetrical around the center position O may be formed by setting the outer edge shape of the circular emission region D of target particles in a circular shape (in which the entire shape of the circular emission region D may be circular or annular).

As a method of forming the circular emission region D, a case in which the magnets 5a illustrated in FIG. 10 extend radially toward the rotation shaft 55 and magnets having a length corresponding to the radius of the emission regions D are rotated may be exemplified. Alternatively, magnets having magnetic field forming surfaces (not illustrated) corresponding to the emission region D may be fixedly arranged.

The emission region D formed as a partial region of the target 41 is not limited to the case of a circular shape or an annular shape. For example, the emission region D having another shape such as a square or an equilateral triangle may be formed in correspondence with the examples described with reference to FIGS. 8 and 9.

FIG. 4 and FIGS. 6 to 11 illustrate the cases in which the targets 41 and 41b to 41d are enclosed in the circle R when viewed from above in a plan view. However, the targets 41 and 41b to 41d may be provided to be larger than the circle R such that, for example, the entire surfaces of the wafers W become the overlapping regions OR.

According to the present disclosure, a sputtering process can be uniformly performed on a plurality of substrates arranged in a common processing container.

It should be understood that the embodiments disclosed herein are exemplary in all respects and are not restrictive. The above-described embodiments may be omitted, replaced, or modified in various forms without departing from the scope and spirit of the appended claims.

What is claimed is:

1. An apparatus for performing a sputtering process on a substrate, comprising:
a processing container configured to accommodate a plurality of substrates;
a plurality of stages provided inside the processing container to respectively place the plurality of substrates thereon and disposed to be arranged along a circle surrounding a preset center position; and
a target disposed at a position above the plurality of stages to cause target particles to be emitted by plasma formed inside the processing container such that the target particles adhere to the plurality of substrates respectively placed on the plurality of stages,
wherein the plurality of stages are arranged such that an emission region in which the target particles are emitted from the target and overlapping regions in which the plurality of substrates respectively placed on the plurality of stages overlap are arranged at positions that are rotationally symmetrical around the preset center position when viewed in a plan view from above the target.

2. The apparatus of claim 1, wherein each of the plurality of stages includes a rotation mechanism configured to rotate the stage around a vertical axis passing through a center of the substrate placed on the stage.

3. The apparatus of claim 2, wherein the circle surrounding the preset center position has a diameter that is set to a dimension in which the circle encloses the emission region when viewed in the plan view from above the target.

4. The apparatus of claim 3, further comprising:
a magnet provided on a rear side of the target when viewed from the stage to adjust a state of the plasma; and
a magnet moving mechanism configured to move the magnet along a rear surface of the target.

5. The apparatus of claim 4, wherein the emission region is an entire surface of the target exposed inside the processing container, and the magnet moving mechanism is further configured to move the magnet such that the entire surface of the target is enclosed in a region in which the magnet moves when viewed in the plan view from above the target.

6. The apparatus of claim 5, wherein the emission region has a circular outer edge when viewed in the plan view from above the target.

7. The apparatus of claim 6, wherein the emission region having the circular outer edge has an annular shape.

8. The apparatus of claim 7, wherein the magnet is provided to extend along a radial direction of the emission region having the circular outer edge, and the magnet moving mechanism is further configured to move the magnet along a circumferential direction of the emission region.

9. The apparatus of claim 1, wherein the circle surrounding the preset center position has a diameter that is set to a dimension in which the circle encloses the emission region when viewed in the plan view from above the target.

10. The apparatus of claim 1, further comprising:
a magnet provided on a rear side of the target when viewed from the stage to adjust a state of the plasma; and
a magnet moving mechanism configured to move the magnet along a rear surface of the target.

11. The apparatus of claim 4, wherein the emission region is a partial region of the target exposed inside the processing container, and the magnet moving mechanism is further configured to move the magnet to correspond to a shape of the emission region when viewed in the plan view from above the target.

12. A method of performing a sputtering process on a substrate, the method comprising:
accommodating a plurality of substrates inside a processing container and placing the plurality of substrates on a plurality of stages, respectively, wherein the plurality of stages are provided inside the processing container and disposed to be arranged along a circle surrounding a preset center position; and
causing target particles to adhere the plurality of substrates by causing the target particles to be emitted from a target disposed at a position above the plurality of stages by plasma formed inside the processing container,
wherein the causing the target particles to adhere to the plurality of substrates is performed using the plurality of stages, which are arranged such that an emission region in which the target particles are emitted from the target and overlapping regions in which the plurality of substrates respectively placed on the plurality of stages overlap are arranged at positions that are rotationally symmetrical around the preset center position when viewed in a plan view from above the target.

13. The method of claim 12, wherein the causing the target particles to adhere to the plurality of substrates includes rotating each of the plurality of stages around a vertical axis passing through a center of the substrate placed on the stage.

14. The method of claim 13, wherein the circle surrounding the preset center position has a diameter that is set to a dimension in which the circle encloses the emission region when viewed in the plan view from above the target.

15. The method of claim 14, wherein the causing the target particles to adhere to the plurality of substrates includes moving a magnet along a rear surface of the target, the magnet being provided on a rear side of the target when viewed from the stage to adjust a state of the plasma.

16. The method of claim 15, wherein the emission region is an entire surface of the target exposed inside the processing container, and the moving the magnet includes moving the magnet such that the entire surface of the target is enclosed in a region in which the magnet moves when viewed in the plan view from above the target.

17. The method of claim 16, wherein the emission region has a circular outer edge when viewed in the plan view from above the target.

18. The method of claim 17, wherein the emission region having the circular outer edge has an annular shape.

19. The method of claim 18, wherein the magnet is provided to extend along a radial direction of the emission region having the circular outer edge, and the moving the magnet includes moving the magnet along a circumferential direction of the emission region.

20. The method of claim 15, wherein the emission region is a partial region of the target exposed inside the processing container, and the moving the magnet includes moving the magnet to correspond to a shape of the emission region when viewed in the plan view from above the target.
